(19) United States
(12) Patent Application Publication
(10) Pub. No.: US 2014/0239291 A1
(43) Pub. Date: Aug. 28, 2014

(54) METAL-OXIDE SEMICONDUCTOR THIN FILM TRANSISTORS AND METHODS OF MANUFACTURING THE SAME

(71) Applicant: Samsung Electronics Co., Ltd., Suwon-Si (KR)

(72) Inventors: Kyoung-seok SON, Seoul (KR); Myung-kwan RYU, Yongin-si (KR); Jae-Kyeong JEONG, Incheon (KR)

(73) Assignees: INHA-INDUSTRY PARTNERSHIP INSTITUTE, Incheon (KR); SAMSUNG ELECTRONICS CO., LTD., Suwon-Si (KR)

(21) Appl. No.: 14/062,137

(22) Filed: Oct. 24, 2013

(30) Foreign Application Priority Data
Feb. 27, 2013 (KR) 10-2013-0021386

(51) Int. Cl. H01L 29/786; H01L 29/24; H01L 29/66

(52) U.S. Cl. CPC H01L 29/78693; H01L 29/66969; H01L 29/247
USPC 257/43; 438/104

(57) ABSTRACT

According to example embodiments a TFT includes: a substrate; a gate electrode on the substrate; a gate insulating layer on the gate electrode; a channel layer on the gate insulating layer, the channel layer including an indium-rich metal-oxide layer; a first electrode on one end of the channel layer; a second electrode on the other end of the channel layer; and a passivation layer on the channel layer between the first and second electrodes.

### CROSS-REFERENCE TO RELATED APPLICATIONS

This application claims priority under 35 U.S.C. §119 to Korean Patent Application No. 10-2013-0021386, filed on Feb. 27, 2013, in the Korean Intellectual Property Office, the disclosure of which is incorporated herein in its entirety by reference.

### BACKGROUND

1. Field

The present disclosure relates to semiconductor devices and/or methods of manufacturing the same, and more particularly, to metal-oxide semiconductor thin film transistors (TFTs) and/or methods of manufacturing the same.

2. Description of the Related Art

A liquid crystal display (LCD) may include an amorphous silicon TFT as a driving device. However, such a TFT may have a mobility of less than about 0.5 cm²/Vs.

Recently, research and development for a TFT formed of a metal-oxide semiconductor, which may be used as a driving device of a Thin Film Transistor-Liquid Crystal Display (TFT-LCD) or an Active Matrix Organic Light-emitting Diode (AMOLED), has been made.

A TFT using a metal-oxide semiconductor may secure a large area, high mobility, and lower manufacturing costs.

A TFT using IGZO(InGaZrO₂) as a metal-oxide semiconductor may have a mobility of about 10 cm²/Vs. However, a mobility of more than 30 cm²/Vs may be desired for some next generation displays. Moreover, if mobility increases, electrical and optical reliability of some metal-oxide semiconductor TFTs may deteriorate.

### SUMMARY

Example embodiments relate to thin film transistors (TFTs) for improving electrical and optical characteristics while ensuring high mobility.

Example embodiments also relate to methods of manufacturing TFTs.

Additional aspects will be set forth in part in the description that follows and, in part, will be apparent from the description, or may be learned by practice of example embodiments.

According to example embodiments, a TFT includes: a substrate; a gate electrode on the substrate; a gate insulating layer on the gate electrode; a channel layer on the gate insulating layer; a first electrode on one end of the channel layer; a second electrode on an other end of the channel layer; and a passivation layer on the channel layer between the first and second electrodes. The channel layer includes an indium-rich metal-oxide layer.

In example embodiments, the passivation layer may be a single layer or a multilayer.

In example embodiments, the passivation layer may include aluminum oxide.

In example embodiments, the passivation layer may be a multilayer, structure including an aluminum oxide layer and a silicon oxide layer.

In example embodiments, the passivation layer may be a structure including an aluminum oxide layer and a silicon nitride layer.

In example embodiments, an indium content of the channel layer may be about 40% or more. For example, an indium content of the channel layer may be about 40 at % or more.

In example embodiments, the indium-rich metal-oxide layer may include one of an IZO layer, an ITO layer, an IGO layer, an IGZO layer, and an IZTO layer.

According to example embodiments, a TFT includes: a substrate; a channel layer on the substrate; source and drain electrodes that are separated from each other on the channel layer; a gate insulating layer on the channel layer between the source and drain electrodes; and a gate electrode on the gate insulating layer. The channel layer includes an indium-rich metal-oxide layer

In example embodiments, the gate insulating layer may be a passivation layer of the channel layer, and may be a single layer or a multilayer.

In example embodiments, the gate insulating layer may include an aluminum oxide.

In example embodiments, the gate insulating layer may be a multilayer structure including an aluminum oxide layer and a silicon oxide layer.

In example embodiments, the gate insulating layer may be a multilayer structure including an aluminum oxide layer and a silicon nitride layer.

In example embodiments, an indium content of the channel layer may be about 40% or more.

In example embodiments, the indium-rich metal-oxide layer may include one of an IZO layer, an ITO layer, an IGO layer, an IGZO layer, and an IZTO layer.

In example embodiments, the source and drain electrodes may extend on the gate insulating layer.

In example embodiments, TFT may further include an interlayer insulating layer on the gate electrode, and the source and drain electrodes may extend on the interlayer insulating layer.

According to example embodiments, a method of manufacturing a TFT includes: forming a gate electrode on a substrate; forming a gate insulating layer, the gate insulating layer being one of on the gate electrode and between the gate electrode and the substrate; forming a channel layer that faces the gate electrode with the gate insulating layer being between the channel layer and the gate electrode; and forming source and drain electrodes on both sides of the channel layer, respectively. The channel layer is formed with an indium-rich metal-oxide layer.

In example embodiments, the forming the gate electrode may include forming the gate electrode below the gate insulating layer; and the method may further include forming a passivation layer on the channel layer between the source and drain electrodes.

In example embodiments, the passivation layer may include an aluminum oxide layer and the passivation layer may be formed of a single layer or a multilayer.

In example embodiments, the forming the gate electrode may include forming the gate electrode on the gate insulating layer.

In example embodiments, an indium content of the channel layer may be about 40% or more. For example, an indium content of the channel layer may be about 40 at % or more.

In example embodiments, the indium-rich metal-oxide layer may include one of an IZO layer, an ITO layer, an IGO layer, an IGZO layer, and an IZTO layer.

In example embodiments, the method may further include: forming an interlayer insulating layer to cover the gate electrode; forming a via hole that penetrates the interlayer insulating layer and the gate insulating layer and exposes the channel layer; and forming the source and drain electrodes in the via hole and on the interlayer insulating layer.

In example embodiments, the forming the gate insulating layer may include forming the gate insulating layer on the channel layer, and the forming the source and drain electrodes may include forming a via hole in the gate insulating layer to expose the channel layer, and forming the source and drain electrodes in the via hole and on the gate insulating layer.

In example embodiments, the gate insulating layer may be a passivation layer of the channel layer and may include an aluminum oxide layer, and may be formed of a single layer or a multilayer.

In example embodiments, the method may further include forming the gate electrode on the gate insulating layer between the source and drain electrodes.

In example embodiments, the multilayer may have a stacked layer structure including an aluminum oxide layer and a silicon oxide layer.

In example embodiments, the multilayer may have a stacked layer structure including an aluminum oxide layer and a silicon nitride layer.

In example embodiments, the method may further include performing an oxygen high-pressure annealing process on the channel layer.

The method may further include performing an oxygen high-pressure annealing process on the channel layer before or after the forming the gate insulating layer.

### BRIEF DESCRIPTION OF THE DRAWINGS

These and/or other aspects will become apparent and more readily appreciated from the following description of non-limiting embodiments, taken in conjunction with the accompanying drawings in which like reference characters refer to the same parts throughout the different views. The drawings are not necessarily to scale, emphasis instead being placed upon illustrating features of example embodiments:

FIGS. 1 to 3 are cross-sectional views illustrating a bottom gate structure of a metal-oxide semiconductor TFT according to example embodiments;

FIGS. 4A, 4B, 5 to 6 are cross-sectional views illustrating a top gate structure of a metal-oxide semiconductor TFT according to example embodiments;

FIGS. 7 to 9 are cross-sectional views illustrating a method of manufacturing a metal-oxide semiconductor TFT having a bottom gate structure according to example embodiments;

FIGS. 10, 11A, 11B, 12A, and 12B are cross-sectional views illustrating methods of manufacturing a metal-oxide semiconductor TFT having a top gate structure according to example embodiments;

FIGS. 13 to 17 are cross-sectional views illustrating a method of manufacturing a metal-oxide semiconductor TFT having a top gate structure according to example embodiments;

FIGS. 18 to 21 are cross-sectional views illustrating a method of manufacturing a metal-oxide semiconductor TFT having a top gate structure according to example embodiments;

FIG. 22 is a graph illustrating the changes in a current-voltage characteristic before and after an Al₂O₃ passivation layer is provided as a channel passivation layer in a TFT according to example embodiments;

FIG. 23 is a graph illustrating the changes in a current-voltage characteristic measured when an Al₂O₃ passivation layer is formed as a channel passivation layer in a TFT according to example embodiments and then an O₂ HPA process is performed on its result;

FIG. 24 is graph illustrating experimental results to evaluate an instability negative bias stress (NBS) according to whether to perform an O₂ HPA process on a TFT according to example embodiments;

FIG. 25 is graph illustrating the experimental results to evaluate a negative illumination bias stress (NIBS) reliability according to whether to perform an O₂ HPA process on a TFT according to example embodiments; and

FIG. 26 is a table illustrating the experimental result of an X-ray photoelectron spectroscopy (XPS) analysis on a channel layer of a TFT according to example embodiments.

### DETAILED DESCRIPTION

Example embodiments will now be described more fully with reference to the accompanying drawings, in which some example embodiments are shown. Example embodiments, may, however, be embodied in many different forms and should not be construed as being limited to the embodiments set forth herein; rather, these example embodiments are provided so that this disclosure will be thorough and complete, and will fully convey the scope of example embodiments of inventive concepts to those of ordinary skill in the art. In the drawings, the thicknesses of layers and regions are exaggerated for clarity. Like reference numerals in the drawings denote like elements, and thus their description may be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof. Expressions such as “at least one of,” when preceding a list of elements, modify the entire list of elements and do not modify the individual elements of the list.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Hereinafter, a metal-oxide semiconductor thin film transistor (TFT) according to example embodiments and a method of manufacturing the same will be described in more detail with reference to the accompanying drawings.

First, a metal-oxide semiconductor TFT will be described according to example embodiments.

FIG. 1 is a cross-sectional view illustrating a bottom gate structure of a metal-oxide semiconductor TFT according to example embodiments.

Referring to FIG. 1, a gate layer 12 is disposed on a substrate 10. The gate layer 12 is used as a gate electrode. The gate layer 12 may be a silicon layer doped with a conductive impurity. A gate insulating layer 14 may be disposed on the gate layer 12. The gate insulating layer 14 may be a silicon oxide layer or a silicon nitride layer. A channel layer 16 is disposed on the gate insulating layer 14. The channel layer 16 may be a metal-oxide semiconductor layer containing an increased content of a specific component. For example, the channel layer 16 may be an indium-rich metal-oxide semiconductor layer. The amount of Indium (In) in the indium-rich metal-oxide semiconductor layer may be more than about 40%. For example, the amount of Indium (In) in the indium-rich metal-oxide semiconductor layer may be about 40 at % or more. The indium-rich metal-oxide semiconductor layer may include one of an IZO layer, an In-rich ITO layer, an IGO layer, an IGZO layer, and an IZTO layer. One side of the channel layer 16 contacts a first electrode 18, and the other side of the channel layer 16 contacts a second electrode 20. The first and second electrodes 18 and 20 are separated from each other. One of them may be a source electrode and the other may be a drain electrode. The first and second electrodes 18 and 20 may be transparent electrodes, for example, ITO electrodes. The first and second electrodes 18 and 20 may cover a portion of the channel layer 16. The channel layer 16 exposed between the first and second electrodes 18 and 20 is covered with a channel passivation layer 22. The channel passivation layer 22 may be a material layer including at least an aluminum oxide layer formed through an oxide high-pressure thermal treatment. The aluminum oxide layer may be an Al₂O₃ layer. The channel passivation layer 22 may be a single layer. The channel passivation layer 22 may be a plurality of layers. For example, as shown in an enlarged first area A1 on the right, the channel passivation layer 22 may include sequentially-stacked first and second passivation layers 22a and 22b. The first passivation layer 22a may be an aluminum oxide layer. The second passivation layer 22b may be an oxide layer or a nitride layer, for example, a silicon oxide layer or a silicon nitride layer. The channel passivation layer 22 may extend on the first and second electrodes 18 and 20 and may overlap them. The channel passivation layer 22 may alternatively be arranged to not overlap the first and second electrodes 18 and 20. For example, the channel passivation layer 22 may have the same height as the first and second electrodes 18 and 20.

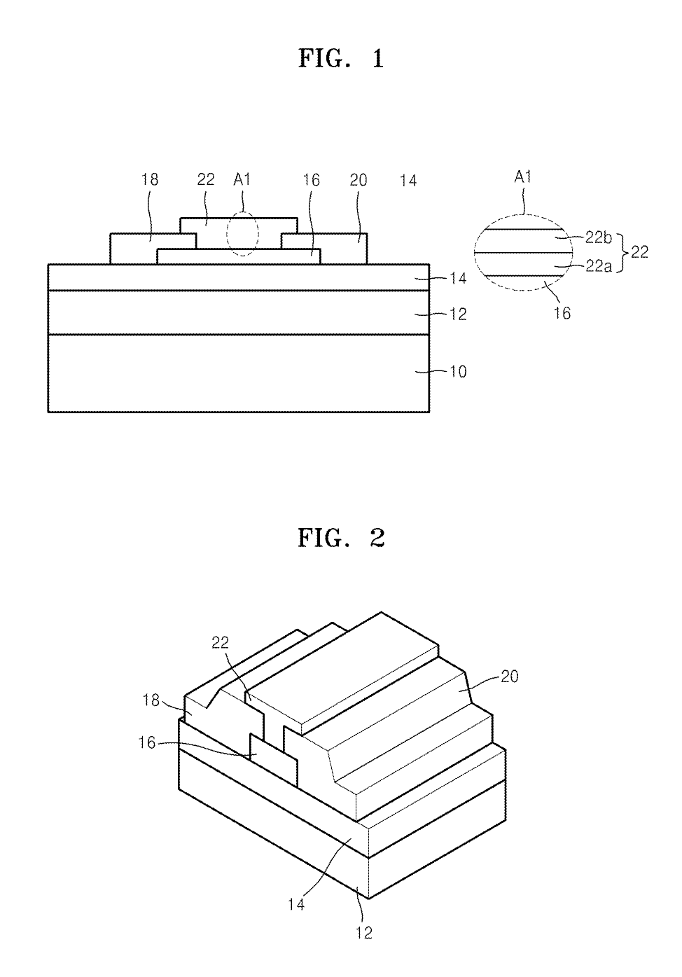

FIG. 2 is a perspective view of FIG. 1. The substrate 10 is not illustrated in FIG. 2 for conciseness.

Referring to FIG. 2, a stacked form between the gate layer 12, the gate insulating layer 14, the channel layer 16, the first and second electrodes 18 and 20, and the channel passivation layer 22 and a stacked relation between the layers can be seen more clearly.

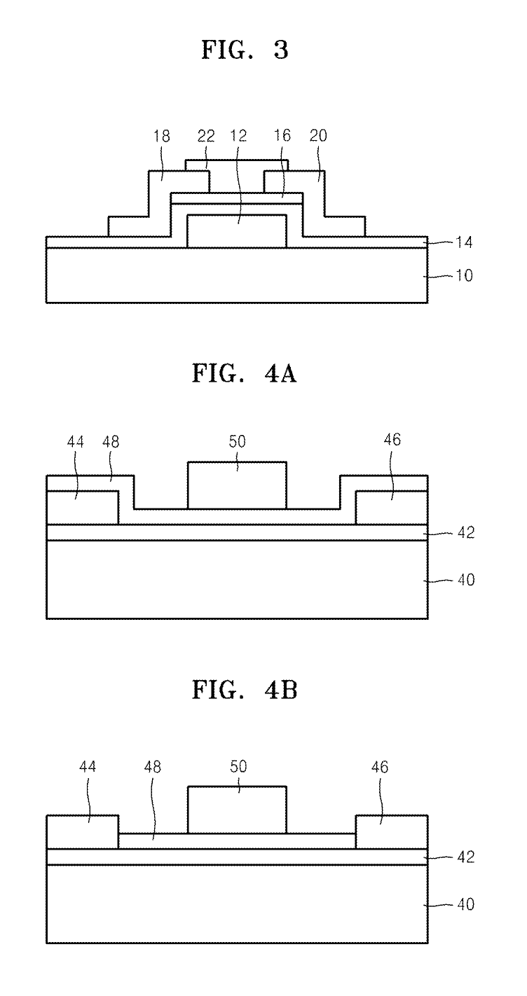

FIG. 3 is a cross-sectional view illustrating a bottom gate structure of a metal-oxide semiconductor TFT according to example embodiments. Like reference numerals refer to like elements throughout FIGS. 1 and 2.

Referring to FIG. 3, the gate layer 12 is disposed on a portion of the substrate 10. The gate insulating layer 14 is formed on the substrate 10 to cover the gate layer 12. The channel layer 16 is disposed on a portion of the gate insulating layer 14 covering a top surface of the gate layer 12. Portions of the both sides of the channel layer 16 are covered with the first and second electrodes 18 and 20. The first and second electrodes 18 and 20 may directly contact the channel layer 16. The first and second electrodes 18 and 20 are formed on the gate insulating layer 14. The channel passivation layer 22 is formed on the exposed channel layer 16 between the first and second electrodes 18 and 20. A portion of the channel passivation layer 22 may extend on the first and second electrodes 18 and 20.

FIGS. 4A and 4B are cross-sectional view illustrating top gate structures of metal-oxide semiconductors TFTs according to example embodiments. Like reference numerals refer to like elements throughout FIGS. 1 to 3, 4A, and 4B.

Referring to FIG. 4A, a channel layer 42 is disposed on a substrate 40. The substrate 40 may be a silicon substrate. The channel layer 42 may be the same as the channel layer 16 of FIG. 1. Separated third and fourth electrodes 44 and 46 are disposed on the channel layer 42. The third and fourth electrodes 44 and 46 may be respectively the same as the first and second electrodes 18 and 20 of FIG. 1. A gate insulating layer 48 is disposed on the channel layer 42 to cover the third and fourth electrodes 44 and 46. The gate insulating layer 48 may be formed of the same configuration material as the channel passivation layer 22 of FIG. 1. The gate insulating layer 48 serves to protect the channel layer 42. As shown in FIG. 4B, the gate insulating layer 48 may be disposed on only the channel layer 42 between the third and fourth electrodes 44 and 46. A gate electrode 50 is disposed on the gate insulating layer 48. The gate electrode 50 may be the same as the gate layer 12 of FIG. 1. The gate electrode 50 is disposed between the third and fourth electrodes 44 and 46.

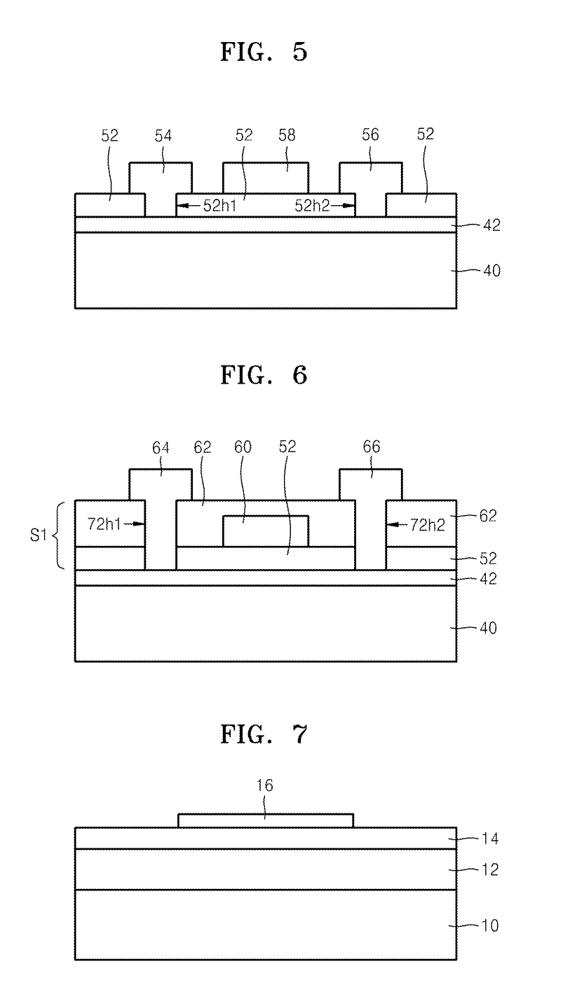

FIG. 5 is a cross-sectional view illustrating a TFT having a co-planar structure, as a metal-oxide semiconductor TFT having a top gate, according to example embodiments.

Referring to FIG. 5, the channel layer 42 is disposed on the substrate 40. The channel layer 42 may be an In-rich channel layer. An insulating layer 52 is formed on the channel layer 42. The insulating layer 52 may serve as a gate insulating layer. The insulating layer 52 may serve to protect the channel layer 42. The insulating layer 52 may be formed of the same configuration material as the channel passivation layer 22 of FIG. 1. Separated via holes 52h1 and 52h2 are formed in the insulating layer 52. A portion of the channel layer 42 is exposed through the via holes 52h1 and 52h2. Fifth and sixth electrodes 54 and 56 and a gate electrode 58 are disposed on the insulating layer 52. The fifth and sixth electrodes 54 and 56 and the gate electrode 58 are at the same height. The fifth and sixth electrodes 54 and 56 may be respectively the same as the third and fourth electrodes 44 and 46 of FIG. 4. The fifth electrode 54 fills the first via hole 52h1 and contacts the channel layer 42. The sixth electrode 56 fills the second via hole 52h2 and contacts the channel layer 42. The gate electrode 58 is disposed between the fifth and sixth electrodes 54 and 56.

FIG. 6 is a cross-sectional view illustrating a top gate structure of a metal-oxide semiconductor TFT according to example embodiments. Like reference numerals refer to like elements throughout FIGS. 1 to 6.

Referring to FIG. 6, the channel layer 42 is disposed on the substrate 40, and the insulating layer 52 is disposed on the channel layer 42. A gate electrode 60 is disposed on a portion of the insulating layer 52. An interlayer insulating layer 62 is formed on the insulating layer 52 to cover the gate electrode 60. Third and fourth via holes 72h1 and 72h2 are formed in an insulating layer stack 51 including the insulating layer 52 and the interlayer insulating layer 62. The channel layer 42 is exposed through the third and fourth via holes 72h1 and 72h2. The gate electrode 60 is disposed between the third and fourth via holes 72h1 and 72h2. Separated seventh and eighth electrodes 64 and 66 are disposed on the interlayer insulating layer 62. The seventh and eighth electrodes 64 and 66 may be respectively the same as the fifth and sixth electrodes 54 and 56 of FIG. 5. The seventh electrode 64 fills the third via hole 72h1 and contacts the channel layer 42. The eighth electrode 66 fills the fourth via hole 72h2 and contacts the channel layer 42.

Hereafter, methods of manufacturing metal-oxide semiconductor TFTs, according to example embodiments, are described with reference to FIGS. 7 to 21. Like reference numerals refer to like elements throughout FIGS. 1 to 21 and their repeated descriptions are omitted.

FIGS. 7 to 9 are views illustrating a method of manufacturing the TFT of FIG. 1 (hereinafter, a first manufacturing method) step-by-step.

Referring to FIG. 7, the gate layer 12 is disposed on the substrate 10. The gate insulating layer 14 is formed on the gate layer 12. The gate layer 12 and the gate insulating layer 14 may be formed using a typical material film deposition device through a CVD method or a sputtering method. Another type of deposition method other than CVD may be used to form the gate layer 12 and the gate insulating layer 14. The channel layer 16 is formed on a portion of the gate insulating layer 14. The channel layer 16 may be formed by forming a material layer to be used as the channel layer 16 on the gate insulating layer 14, and then patterning the material layer. The channel layer 16 may be the In-rich metal-oxide semiconductor layer as mentioned above. The In-rich may be obtained by supplying an In component or a precursor including In to a deposition device for forming the channel layer 16 more than the amount (hereinafter, referred to as a normal value) supplied when a typical metal-oxide semiconductor is formed. In order to form the channel layer 16, an In component or a precursor including In, which is greater than the normal value by about 40%, may be supplied. For example, in order to form the channel layer 16, an In component or a precursor including In, which is greater than the normal value (e.g., 40 at %), may be supplied. However, example embodiments are not limited thereto.

Moreover, the channel layer 16 may be formed through an opposite method. For example, when components for a metal-oxide semiconductor layer are supplied to form the channel layer 16, the channel layer 16 having a relatively In-rich result may be formed by supplying the contents of remaining components other than In to be less than the normal value.

An In-rich IZO layer is formed as the channel layer, and when a sputtering method is applied, the deposition process conditions may be as follows:

<Process Conditions>

Power: 100 W

Time: 10 min

Ar/O₂=14/6 (Po₂=30%)

Working pressure: 2 mTorr

Annealing condition: 300° C., 1 hr, ambient

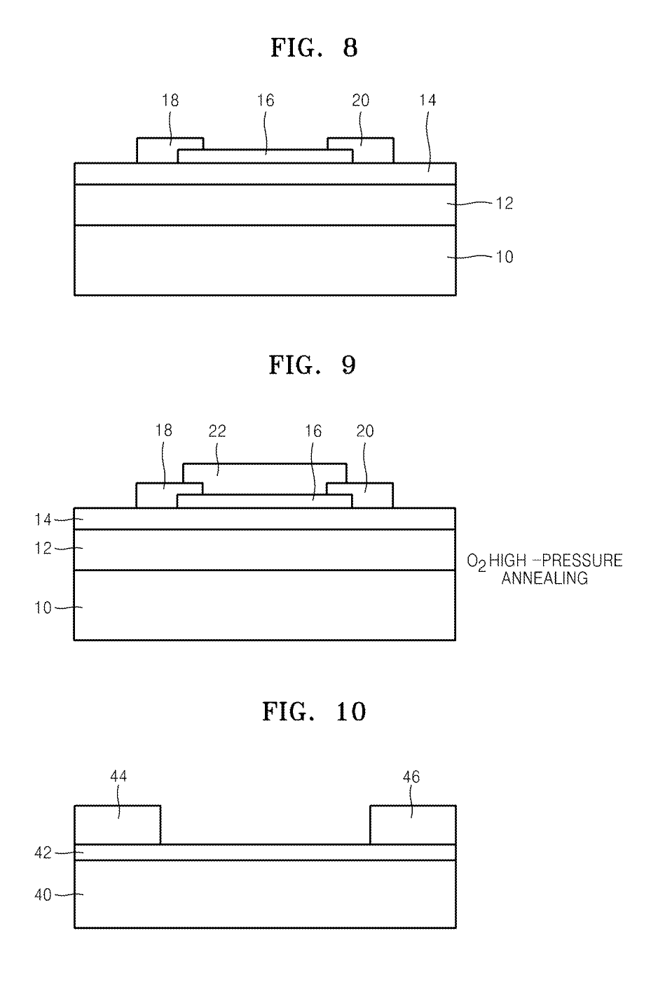

Then, referring to FIG. 8, the first and second electrodes 18 and 20 are formed on the gate insulating layer 14. The first and second electrodes 18 and 20 are formed spaced apart from each other. The first electrode 18 contacts one side of the channel layer 16, and the second electrode 20 contacts the other side of the channel layer 16. The first and second electrodes 18 and 20 may be formed by forming a material layer that covers the channel layer 16 on the gate insulating layer 14 and patterning the material layer to the forms of the first and second electrodes 18 and 20. The first and second electrodes 18 and 20 may be formed of a transparent material, for example, ITO.

Then, referring to FIG. 9, the channel passivation layer 22 is formed to cover the channel layer 16 between the first and second electrodes 18 and 20. The channel passivation layer 22 may be formed through an atomic layer deposition (ALD) method. The channel passivation layer 22 may be formed of a single layer or a multilayer. When the channel passivation layer 22 is formed of a multilayer, after an aluminum oxide layer is formed on the channel layer 16, another oxide layer or nitride layer may be formed on the aluminum oxide layer. At this point, the aluminum oxide layer may be formed through an ALD method, and the other oxide layer or nitride layer may be formed through another deposition method other than the ALD method. An Al₂O₃ layer is formed as the channel passivation layer 22, and when an ALD method is applied, the process conditions may be as follows:

<Process Conditions>

Source: TMA, feeding 1 sec

Oxidant: O₃, (9-10 wt %) feeding 2 sec

Process temperature: 215° C.

Cycle: 120 (˜30 min)

Thickness: ˜15 nm

Moreover, when the gate layer 12 is formed, the gate layer 12 may be patterned on a portion of the substrate 10 and when the gate insulating layer 14 is formed to cover the result of the patterned gate layer 12, as shown in FIG. 3, a TFT having a bottom gate structure may be formed.

Then, a thermal treatment is performed on the channel layer 16 as the result of the channel passivation layer 22 formed is thermally treated. At this point, the thermal treatment may be an oxygen high-pressure heat treatment. That is, the thermal treatment may be performed under a high-pressure oxygen atmosphere. The pressure may be about 0.5 atm to about 20 atm. Additionally, a thermal treatment temperature is about 100° C. to about 500° C.

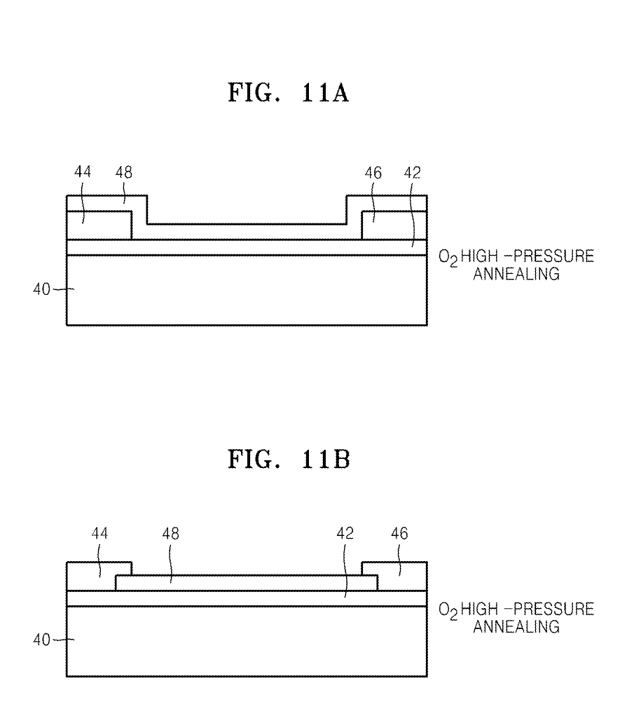

FIGS. 10, 11A, 11B, 12A, and 12B are cross-section views illustrating methods of manufacturing the metal-oxide semiconductor TFTs of FIGS. 4A and 4B step-by-step.

Referring to FIG. 10, the channel layer 42 is disposed on the substrate 40. The channel layer 42 may be formed through another method than the first manufacturing method. Separated third and fourth electrodes 44 and 46 are disposed on the channel layer 42. The third and fourth electrodes 44 and 46 may be formed by forming a material layer used as an electrode on the channel layer 42 and patterning the material layer to obtain the forms of the third and fourth electrodes 44 and 46.

Then, referring to FIG. 11A, the gate insulating layer 48 is formed to cover the channel layer 42 between the third and fourth electrodes 44 and 46. The gate insulating layer 48 may be formed on the third and fourth electrodes 44 and 46. The gate insulating layer 48 serves as a channel passivation layer. As shown in FIG. 11B, the gate insulating layer 48 may be formed on the channel layer 42 between the third and fourth electrodes 44 and 46. Both ends of the gate insulating layer 48 extend below the third and fourth electrodes 44 and 46. The above result may be obtained by forming the gate insulating layer 48 on the channel layer 42 first, removing a portion of the gate insulating layer 48 to obtain a region where the third and fourth electrodes 44 and 46 are to be formed, and forming the third and fourth electrodes 44 and 46 on the region to overlap a portion of the gate insulating layer 48. After the third and fourth electrodes 44 and 46 are formed in such a manner, its result may be thermally treated as shown in FIG. 9. Such a thermal treatment may be performed before the third and fourth electrodes 44 and 46 are formed. For example, after the gate insulating layer 48 is formed on the channel layer 42, a thermal treatment may be performed before a portion of the gate insulating layer 48 is removed.

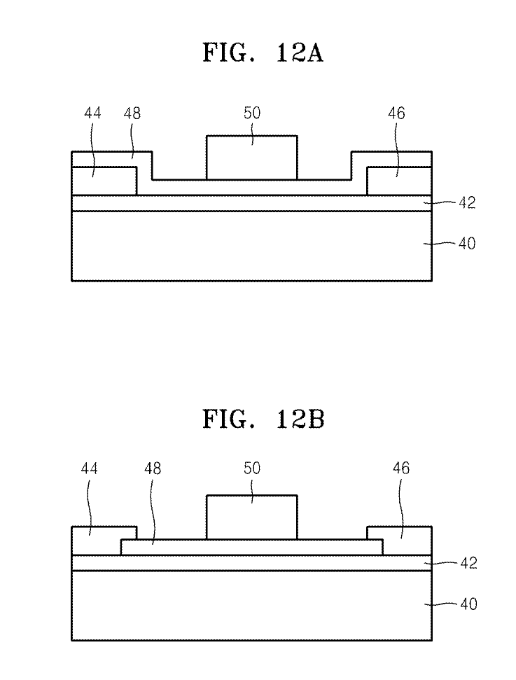

Then, referring to FIGS. 12A and 12B, the gate electrode 50 is formed on the gate insulating layer 48 between the third and fourth electrodes 44 and 46. The gate electrode 50 may be formed by forming a conductive material layer to be used as the gate electrode 50 on the gate insulating layer 48, and then patterning the conductive material layer through a typical photo and etch process. The conductive material layer may be a doped silicon layer, a metal layer, a metal silicide layer, or an alloy layer.

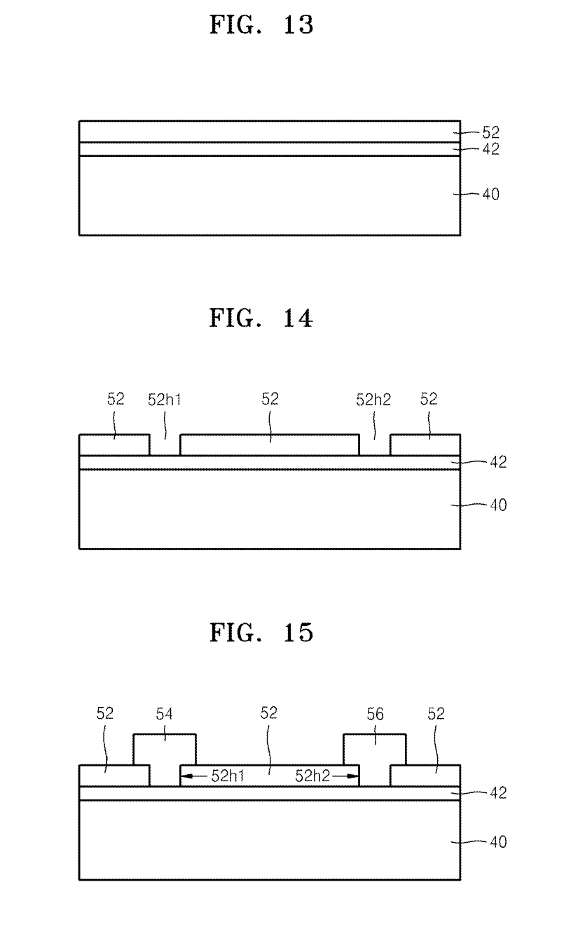

FIGS. 13 to 17 are views illustrating a method of manufacturing the metal-oxide semiconductor TFT of FIG. 5 step-by-step.

Referring to FIG. 13, the channel layer 42 and the insulating layer 52 are sequentially formed on the substrate 40. The insulating layer 52 may serve as a gate insulating layer and a channel passivation layer. After the insulating layer 52 is formed, its result may be thermally treated as shown in FIG. 9.

Then, referring to FIG. 14, the first and second via holes 52h1 and 52h2 are formed in the insulating layer 52. The first and second via holes 52h1 and 52h2 may be formed by forming a photosensitive pattern, through which a portion of the insulating layer 52 is exposed, on the insulating layer 52 and then etching the exposed portion of the insulating layer 52. Then, the photosensitive pattern is removed.

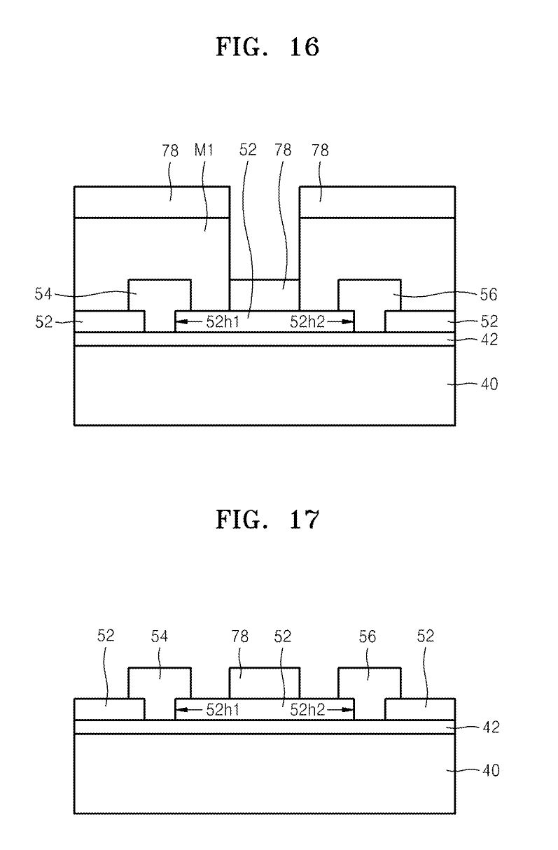

Then, referring to FIG. 15, the fifth electrode 54 is formed on the insulating layer 52 to fill the first via hole 52h1, and the sixth electrode 56 is formed on the insulating layer 52 to fill the second via hole 52h2. The fifth and sixth electrodes 54 and 56 may be formed by forming an electrode material layer that fills the first and second via holes 52h1 and 52h2 and then patterning the electrode material layer through a typical photo and etch process.

Then, referring to FIG. 16, a mask M1 is formed on the insulating layer 52 to cover the fifth and sixth electrodes 54 and 56 and expose a portion of the insulating layer 52. The exposed area of the insulating layer 52 is an area where a gate electrode is to be formed. After the mask M1 is formed, a gate layer 78 is formed to cover the exposed area of the insulating layer 52. The gate layer 78 may be disposed on the mask M1. Then, the mask M1 and the gate layer 78 formed thereon are removed. As a result, as shown in FIG. 17, the gate layer 78 remains only on the insulating layer 52 between the fifth and sixth electrodes 54 and 56. The remaining gate layer 78 on the insulating layer 52 is used as the gate electrode 58 of FIG. 5. The gate layer 78 between the fifth and sixth electrodes 54 and 56 is formed on the same material layer, i.e., the insulating layer 52.

FIGS. 18 to 21 are views illustrating a method of manufacturing the metal-oxide semiconductor TFT of FIG. 6 step-by-step.

Referring to FIG. 18, the channel layer 42 and the insulating layer 52 are sequentially formed on the substrate 40. Then, the gate electrode 60 is formed on the insulating layer 52.

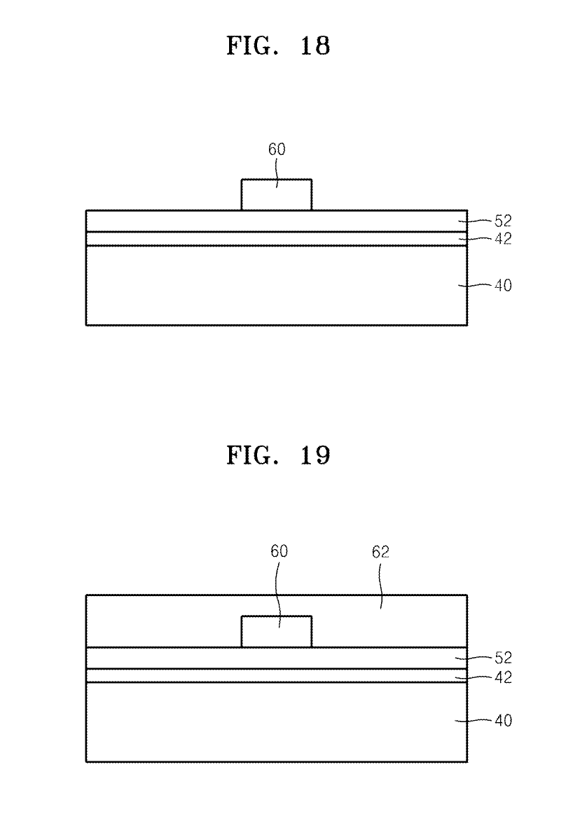

Then, as shown in FIG. 19, the interlayer insulating layer 62 is formed on the insulating layer 52 to cover the gate electrode 60. The top surface of the interlayer insulating layer 62 is planarized.

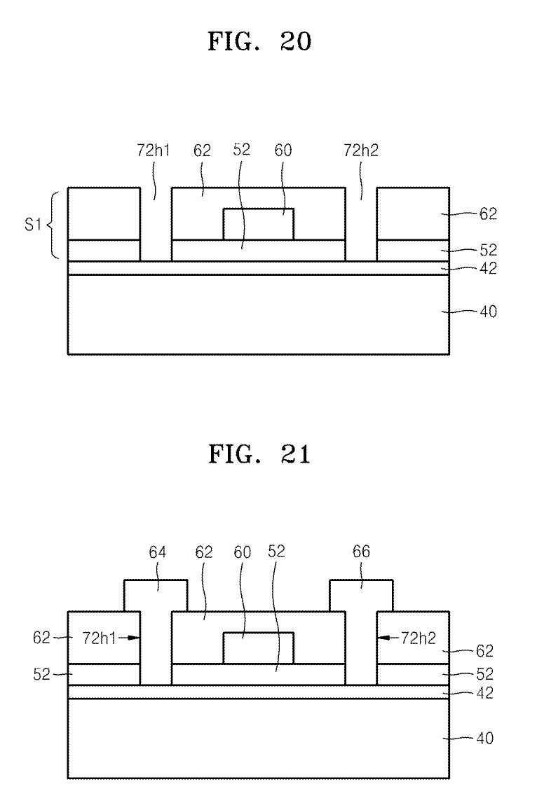

Then, referring to FIG. 20, the third and fourth via holes 72h1 and 72h2, through which the channel layer 42 is exposed, are formed in the insulating layer stack 51 including the insulating layer 52 and the interlayer insulating layer 62. The gate electrode 60 is disposed between the third and fourth via holes 72h1 and 72h2.

Referring to FIG. 21, the seventh electrode 64 is formed on the interlayer insulating layer 62 to fill the third via hole 72h1, and the eighth electrode 66 is formed on the interlayer insulating layer 62 to fill the fourth via hole 72h2. The seventh and eighth electrodes 64 and 66 are spaced apart from each other.

Next, experimental results on the electrical characteristics of a TFT according to example embodiments will be described.

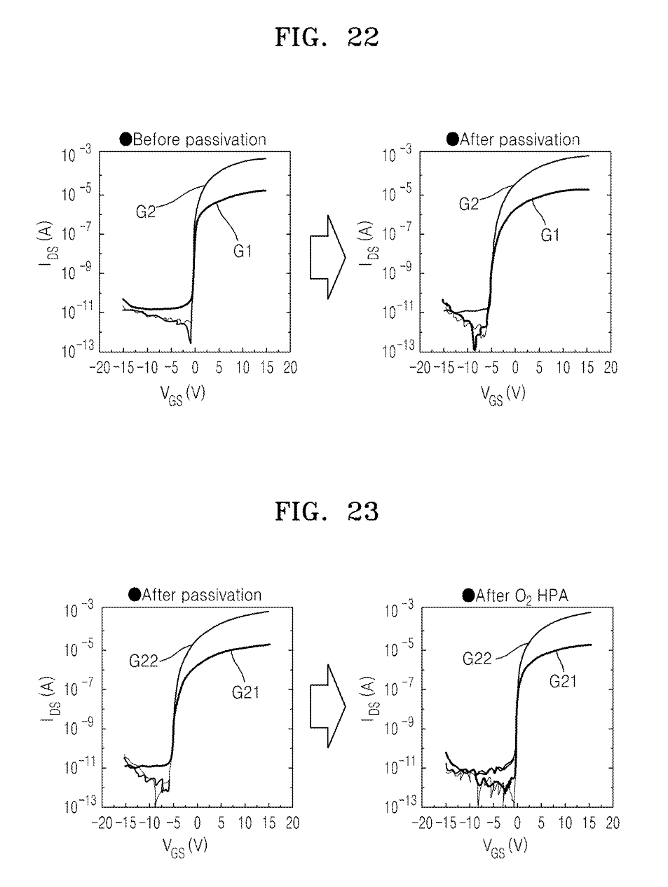

FIG. 22 is a graph illustrating the changes in a current-voltage characteristic before and after an Al₂O₃ passivation layer is provided as a channel passivation layer. As shown in FIG. 22, a first graph G1 indicates a result measured when a source-drain voltage V_{DS} is about 0.1 V. A second graph G2 indicates a result measured when a source-drain voltage V_{DS} is about 0.5 V.

Referring to FIG. 22, after a channel passivation layer is formed, it is shown that a threshold voltage moves by about 4 V in a negative direction. This result is estimated as a phenomenon resulting from when the oxygen absorbed by a channel layer is desorbed before a channel passivation layer is formed, and the amount of change in a threshold voltage may be limited (and/or minimized) through a control of an ALD process, such as an oxygen plasma treatment process.

In addition, there are no changes in the mobility, gate swing, and Ion/off characteristics of a TFT measured before and after the channel protective layer is formed.

FIG. 23 is a graph illustrating the changes in a current-voltage characteristic measured when an Al₂O₃ passivation layer is formed as a channel passivation layer in a TFT according to example embodiments and then an O₂ high pressure annealing (HPA) process is performed on its result.

As shown in FIG. 23, a first graph G21 indicates a result measured when a source-drain voltage V_{DS} is about 0.1 V. A second graph G22 indicates a result measured when a source-drain voltage V_{DS} is about 0.5 V.

Referring to FIG. 23, although a channel passivation layer is formed and a threshold voltage moves in a negative direction, after the O₂ HPA process, the threshold voltage moves in a positive direction again, that is, to the right, and thus becomes the same state as before the channel passivation layer is formed. It is estimated that such a result is obtained due to the fact that oxygen is compulsively supplied to the channel passivation layer through the O₂ HPA process so that the concentration of the oxygen vacancy defects of the channel passivation layer is reduced.

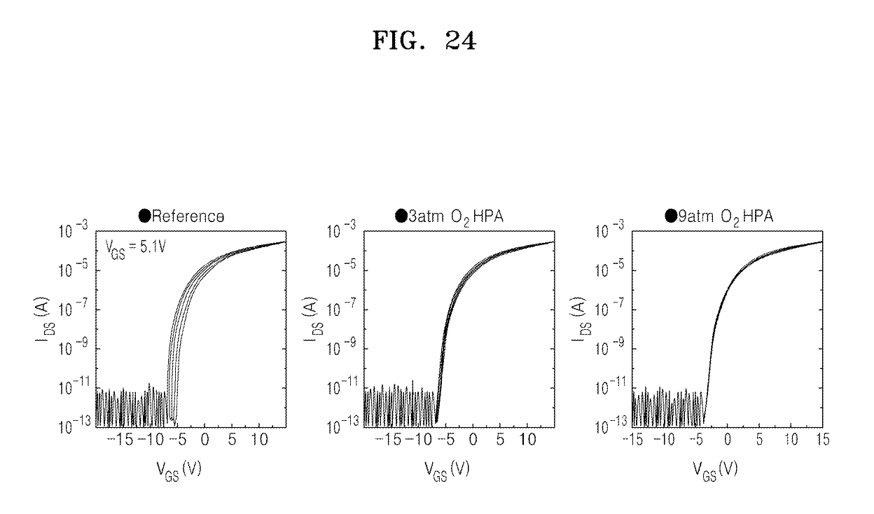

FIG. 24 is view illustrating experimental results to evaluate a negative bias stress (NBS) instability according to whether to perform an O₂ HPA process on a TFT according to example embodiments.

Experiments were conducted with first to third TFTs having an Al₂O₃ channel passivation layer. The first TFT was thermally treated for 1 hr under 0.2 atm and 200° C. The second TFT was thermally treated for 1 hr under 3 atm and 200° C. (O₂ HPA). The third TFT was thermally treated for 1 hr under 9 atm and 200° C. (O₂ HPA). The stress condition for the first to third TFTs was set to V_{GS}=−20V and V_{DS}=5.1V, and a current-voltage characteristic was measured for 1 hr. Such measurements were made at 0 s, 100 s, 300 s, 600 s, 1200 s, 2100 s, and 3600 s.

In FIG. 24, the left graph shows an experimental result for the first TFT. The middle graph shows an experimental result for the second TFT. The right graph shows an experimental result for the third TFT.

Referring to FIG. 24, a horizontal axis represents a gate-source voltage V_{GS} and a vertical axis represents a drain-source current I_{DS}.

When each graph of FIG. 24 is compared, although a thermal treatment was performed at about 0.2 atm (the left graph), a change in a threshold voltage moved to about 1.2 V in a negative direction. However, when a thermal treatment was performed at about 3 atm (the middle graph), a change in a threshold voltage was reduced to about 0.4 V. Moreover, when a thermal treatment was performed at about 9 atm (the right graph), it was confirmed that there was almost no change in a threshold voltage.

The results of FIG. 24 showed that NBS instability was lowered by performing an O₂ HPA process on a result having an Al₂O₃ channel passivation layer. Therefore, the electrical reliability of a TFT may be improved by performing an O₂ HPA process on a TFT having an Al₂O₃ channel passivation layer.

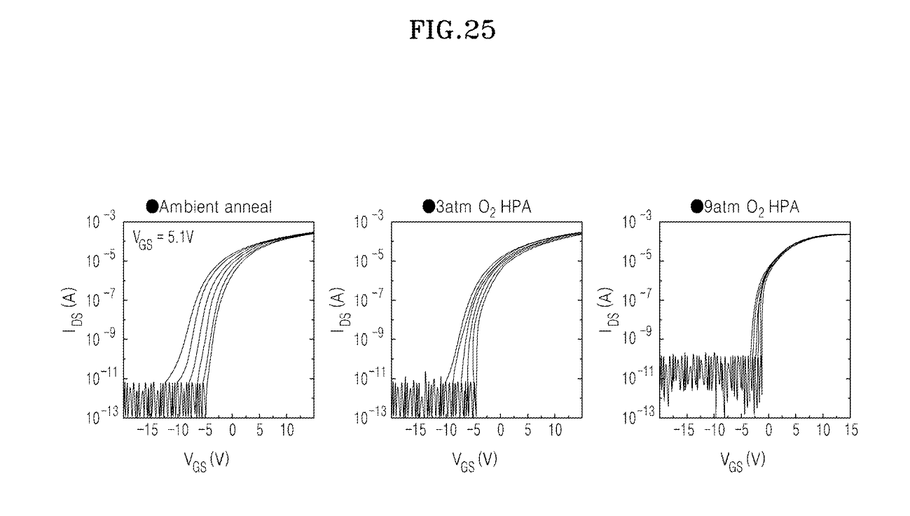

FIG. 25 is view illustrating the experimental results to evaluate a negative illumination bias stress (NIBS) reliability according to whether to perform an O₂ HPA process on a TFT according to example embodiments. Experiments were conducted with fourth to sixth TFTs having no Al₂O₃ channel passivation layer. This experiment did not form a channel passivation layer in order to apply illumination stress to a channel layer.

The fourth TFT was thermally treated for 1 hr under 0.2 atm and 200° C. The fifth TFT was thermally treated for 1 hr under 3 atm and 200° C. (O₂ HPA). The sixth TFT was thermally treated for 1 hr under 9 atm and 200° C. (O₂ HPA). The stress conditions for the fourth to sixth TFTs include a voltage stress condition and an illumination stress condition. The voltage stress condition is V_{GS}=−20V and V_{DS}=5.1V The illumination stress condition is to emit green light (0.06 mW/cm²). At this point, a light-emitting diode is used as a green light source. Under such stress conditions, a current-voltage characteristic was measured for 1 hr. Such measurements were made at 0 s, 100 s, 300 s, 600 s, 1200 s, 2100 s, and 3600 s.

The left graph shows an experimental result for the fourth TFT. The middle graph shows an experimental result for the fifth TFT. The right graph shows an experimental result for the sixth TFT.

Referring to FIG. 25, a horizontal axis represents a gate-source voltage V_{GS} and a vertical axis represents a drain-source current I_{DS}.

When each graph of FIG. 25 is compared, when a thermal treatment was performed at about 0.2 atm (the left graph), a change in a threshold voltage moved to about 3.7 V in a negative direction. However, when a thermal treatment was performed at about 3 atm (the middle graph), a change in a threshold voltage moved to about 2.2 V in a negative direction. Moreover, when a thermal treatment was performed at about 9 atm (the right graph), a change in a threshold voltage moved to about 0.9 V in a negative direction.

The result of FIG. 25 shows that the NBIS reliability is improved by an O₂ HPA process. The reliability improvement of NBIS means that the electrical reliability of a TFT is improved while light is emitted. That is, it means that the optical reliability of a TFT is improved.

Referring to FIGS. 24 and 25, in relation to a TFT using a metal-oxide semiconductor as a channel layer according to example embodiments, high mobility is obtained and electrical and optical reliability are improved.

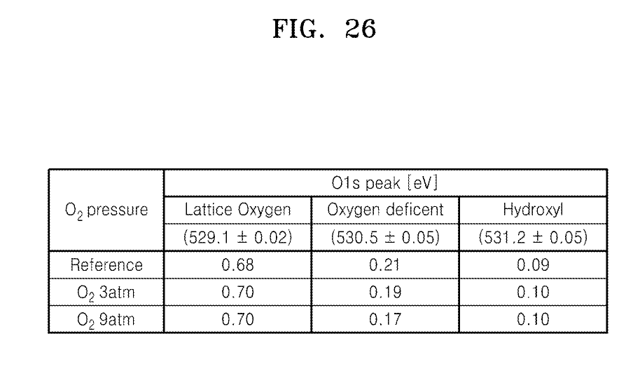

FIG. 26 is a table illustrating the experimental result of an X-ray photoelectron spectroscopy (XPS) analysis on a channel layer of a TFT according to example embodiments.

The experiments were conducted with seventh to ninth TFTs having an Al₂O₃ channel passivation layer. The seventh TFT was thermally treated for 1 hr under atmospheric pressure, air atmosphere, and 200° C. The eighth TFT was thermally treated for 1 hr under 3 atm and 200° C. (O₂ HPA). The ninth TFT was thermally treated for 1 hr under 9 atm and 200° C. (O₂ HPA).

“Reference” in the table of FIG. 25 represents an XPS analysis result on a channel layer of the seventh TFT. Also, “O₂ 3 atm” represents an XPS analysis result on a channel layer of the eighth TFT. Also, “O₂ 9 atm” represents an XPS analysis result on a channel layer of the ninth TFT. In the table, “Lattice Oxygen” represents a value related to Zn—O bonding in a channel layer. Also, “Oxygen deficient” represents a value indicating oxygen vacancies in a channel layer. Moreover, “Hydroxyl” represents hydroxyl (OH) occurring during an XPS analysis process.

Referring to the table of FIG. 26, values relating to “Lattice Oxygen” and “Hydroxyl” between the seventh to ninth TFTs have no big difference. However, a value relating to “Oxygen deficient” representing oxygen vacancies is reduced further in the order of the seventh TFT to the ninth TFT. That is, as the pressure of an O₂ HPA process on a channel layer increases, the oxygen vacancies of the channel layer are further reduced.

According to the results of FIGS. 24 to 26, while maintaining high mobility, a TFT according to example embodiments may have improved electrical and optical characteristics, because the oxygen vacancies in a channel layer are reduced by performing an O₂ HPA process on the channel layer.

It should be understood that example embodiments described herein should be considered in a descriptive sense only and not for purposes of limitation. Descriptions of features or aspects within each TFT according to example embodiments should typically be considered as available for other similar features or aspects in other TFT according to example embodiments.

While some example embodiments have been particularly shown and described, it will be understood by one of ordinary skill in the art that variations in form and detail may be made therein without departing from the spirit and scope of the claims.

What is claimed is:

1. A thin film transistor (TFT) comprising:
a substrate;
a gate electrode on the substrate;
a gate insulating layer on the gate electrode;
a channel layer on the gate insulating layer,
the channel layer including an indium-rich metal-oxide layer;
a first electrode on one end of the channel layer;
a second electrode on an other end of the channel layer; and
a passivation layer on the channel layer between the first and second electrodes.

2. The TFT of claim 1, wherein the passivation layer comprises aluminum oxide.

3. The TFT of claim 2, wherein the passivation layer further comprises one of a silicon oxide layer and a silicon nitride layer.

4. The TFT of claim 1, wherein an indium content of the channel layer is about 40% or more.

5. The TFT of claim 1, wherein the indium-rich metal-oxide layer includes one of an IZO layer, an ITO layer, an IGO layer, an IGZO layer, and an IZTO layer.

6. A thin film transistor (TFT) comprising:
a substrate;
a channel layer on the substrate,
the channel layer including an indium-rich metal-oxide layer;
source and drain electrodes that are separated from each other on the channel layer;
a gate insulating layer on the channel layer between the source and drain electrodes; and
a gate electrode on the gate insulating layer.

7. The TFT of claim 6, wherein the gate insulating layer comprises aluminum oxide.

8. The TFT of claim 6, wherein the gate insulating layer further comprises one of a silicon oxide layer and a silicon nitride layer.

9. The TFT of claim 6, wherein an indium content of the channel layer is about 40% or more.

10. The TFT of claim 6, wherein the indium-rich metal-oxide layer is one of an IZO layer, an ITO layer, an IGO layer, an IGZO layer, and an IZTO layer.

11. The TFT of claim 6, further comprising:
an interlayer insulating layer on the gate electrode, wherein the source and drain electrodes extend on the interlayer insulating layer.

12. A method of manufacturing a thin film transistor (TFT), the method comprising:
forming a gate electrode on a substrate;
forming a gate insulating layer,
the gate insulating layer being one of on the gate electrode and between the gate electrode and the substrate;
forming a channel layer that faces the gate electrode with the gate insulating being between the channel layer and the gate electrode,
the channel layer including an indium-rich metal oxide layer; and
forming source and drain electrodes on both sides of the channel layer, respectively.

13. The method of claim 12, wherein the forming the gate electrode includes forming the gate electrode below the gate insulating layer; and
the method further includes forming a passivation layer on the channel layer between the source and drain electrodes.

14. The method of claim 13, wherein the passivation layer comprises an aluminum oxide layer.

15. The method of claim 12, further comprising:
forming an interlayer insulating layer on the gate electrode;
forming a via hole that penetrates the interlayer insulating layer and the gate insulating layer and exposes the channel layer; and
forming the source and drain electrodes in the via hole and on the interlayer insulating layer.

16. The method of claim 12, wherein
the forming the gate insulating layer includes forming the gate insulating layer on the channel layer; and
the forming source and drain electrodes comprises:
forming a via hole in the gate insulating layer to expose the channel layer, and
forming the source and drain electrodes in the via hole and on the gate insulating layer.

17. The method of claim 12, wherein an indium content of the channel layer is about 40% or more.

18. The method of claim 12, wherein
the forming the gate insulating layer includes forming the gate insulating layer on the channel layer,
the gate insulating layer is a passivation layer on the channel layer, and the gate insulating layer comprises an aluminum oxide layer.

19. The method of claim 12, further comprising:
performing an oxygen high-pressure annealing process on the channel layer.

20. The method of claim 12, further comprising:
performing an oxygen high-pressure annealing process on the channel layer before or after the forming the gate insulating layer.
